(19) United States
(12) Patent Application Publication
(10) Pub. No.: US 2025/0185487 A1
(43) Pub. Date: Jun. 5, 2025

(54) LIGHT EMITTING DISPLAY DEVICE

(71) Applicant: LG Display Co., Ltd., Seoul (KR)

(72) Inventors: Sung Bin SHIM, Paju-si (KR); Kang Il KIM, Paju-si (KR)

(73) Assignee: LG Display Co., Ltd., Seoul (KR)

(21) Appl. No.: 18/939,955

(22) Filed: Nov. 7, 2024

(30) Foreign Application Priority Data
Dec. 4, 2023 (KR) 10-2023- 0173591

(51) Int. Cl. H10K 59/80; H10K 59/124

(52) U.S. Cl. CPC H10K 59/80518; H10K 59/124; H10K 59/80515

(57) ABSTRACT

Disclosed is a light emitting display device that improves the light emission effect and improves luminance uniformity even when the viewing angle changes by changing the structure in which light emitting portions are arranged. The light emitting display device includes a substrate including a plurality of subpixels, a planarization film on the substrate and including a recess having a bottom surface and an inclined side surface around the bottom surface in each subpixel, a reflective anode provided along the bottom surface and the side surface of the recess, a transparent electrode provided on the reflective anode disposed on the bottom surface of the recess, a pattern overlapping the side surface of the recess with the reflective anode interposed therebetween, an intermediate layer provided on the pattern and the transparent electrode, and a cathode provided on the intermediate layer.

This application claims the benefit of and priority to Korean Patent Application No. 10-2023-0173591, filed on Dec. 4, 2023, which is hereby incorporated by reference as if fully set forth herein.

### BACKGROUND

### Field

The present disclosure relates to a light emitting display device that is capable of expanding light emitting portions to regions overlapping with a bank and of preventing color mixing between adjacent light emitting portions.

### Discussion of the Related Art

With the advent of the information society, there is an increasing demand for various forms of display devices for displaying images.

A light emitting display device that includes light emitting elements to constitute pixels does not require a separate light source unit and is thus advantageous for being slim or flexible and has excellent color purity.

For example, a light emitting element includes two different electrodes and a light emitting layer between the electrodes. When electrons generated from one electrode and holes generated from the other electrode are injected into the light emitting layer, the electrons are combined with the holes to form excitons and the energy of the excitons drops from the excited state to the ground state, thus causing light emission.

Light emitting display devices use banks to define a light emitting portion of each subpixel, but have limited resolution because the areas occupied by the bank do not emit light.

### SUMMARY

Accordingly, the present disclosure is directed to a light emitting display device that substantially obviates one or more problems due to the limitations and disadvantages of the related art.

The light emitting display device of the present disclosure has a recess in the planarization film on which the light emitting element is formed, and the bottom surface of the recess is used for front light emission and the side surface of the recess is used for side light emission to expand the light emitting portion.

In addition, a transparent electrode is further provided on the bottom surface of the recess where the front light is emitted for each subpixel, and the thickness of the transparent electrode is adjusted for each subpixel to improve front luminance depending on the wavelength of each subpixel. In addition, the reflective anode under the transparent electrode is extended to the area that overlaps the pattern defining the front light emitting portion for each subpixel, so that the light generated from the light emitting element within the opening of the pattern is incident on the peripheral side of the recess where the pattern is located and is reflected from the reflective electrode within the area overlapping the pattern, thereby improving light emission in addition to the front light emission. In this case, the optical distance at the peripheral side of the recess is set to correspond to the optical distance of the light emitting element on the bottom, thereby lowering the luminance change due to the viewing angle change and improving the user's visual perception.

Additional advantages, objects, and features of the disclosure will be set forth in part in the description which follows and in part will become apparent to those having ordinary skill in the art upon examination of the following, or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a light emitting display device includes a substrate including a plurality of subpixels, a planarization film on the substrate and including a recess having a bottom surface and an inclined side surface around the bottom surface in each subpixel, a reflective anode provided along the bottom surface and the side surface of the recess, a transparent electrode provided on the reflective anode disposed on the bottom surface of the recess, a pattern overlapping the side surface of the recess with the reflective anode interposed therebetween, an intermediate layer provided on the pattern and the transparent electrode, and a cathode provided on the intermediate layer.

It is to be understood that both the foregoing general description and the following detailed description of the disclosure are by way of example and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate example embodiment(s) of the disclosure and together with the description serve to explain the principle of the disclosure. In the drawings:

FIG. 1 is a schematic diagram illustrating a light emitting display device according to an example embodiment of the present disclosure;

FIG. 2 is a cross-sectional view illustrating a light emitting display device according to an example embodiment of the present disclosure;

FIG. 3 is a cross-sectional view illustrating the first element in area A and the second element in area B of FIG. 2;

FIG. 4 is a graph showing first to fourth light generation and luminance characteristics as a function of viewing angle in the light emitting device according to an example embodiment of the present disclosure;

FIGS. 5 to 7 are cross-sectional views showing intermediate layers included in the light emitting display devices according to various example embodiments of the present disclosure;

FIG. 8 is a diagram illustrating an example of a multilayer configuration of the light emitting layer in the intermediate layer;

FIG. 9 is a diagram showing constructive interference between the reflective anode and cathode for each wavelength of the example first element;

FIG. 10 is a diagram showing the principle of light emission by constructive interference between the reflective anode and cathode of the example first element;

FIG. 11 is a diagram showing the principle of light emission by constructive interference between the reflective anode and cathode of the example second element;

FIG. 12 is a plan view illustrating a light emitting display device according to an example embodiment of the present disclosure;

FIG. 13 is a cross-sectional view taken along line I-I′ of FIG. 12; and

FIG. 14 is a cross-sectional view illustrating a display device according to an example embodiment.

### DETAILED DESCRIPTION

Reference will now be made in detail to example embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the specification, and can differ from the names of elements of actual products. Furthermore, in the following detailed description of the present disclosure, numerous specific details are set forth to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to” or “coupled to” another element or layer, it can be directly connected to or coupled to the other element or layer, or one or more intervening elements or layers can be present.

In describing the various example embodiments of the present disclosure, where terms such as “after,” “subsequently,” “next,” and “before,” are used to describe the temporal relationship between two events, another event can occur therebetween, unless a more limiting term, such as “just,” “immediate(ly),” or “directly,” is used.

In describing the various example embodiments of the present disclosure, terms such as “first” and “second” can be used to describe a variety of components. These terms aim to refer to the same or similar components separately from one another and do not limit the components. Accordingly, throughout the specification, a “first” component can be referred to as a “second” component, or vice versa, within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. Further, for convenience of description, a scale in which each of elements is illustrated in the accompanying drawings can differ from an actual scale. Thus, the illustrated elements are not limited to the specific scale in which they are illustrated in the drawings.

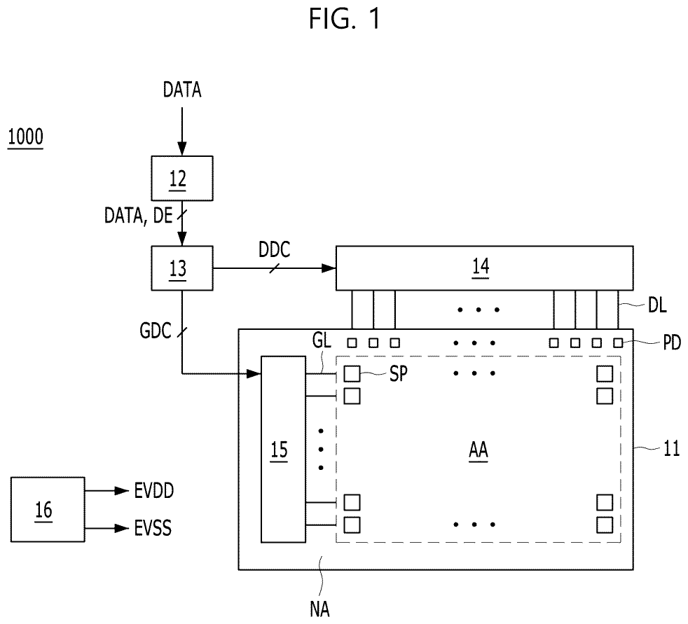

FIG. 1 is a schematic diagram illustrating a light emitting display device according to an example embodiment of the present disclosure.

As shown in FIG. 1, the light emitting display device 1000 according to an embodiment of the present disclosure includes a display panel 11, an image processor 12, a timing controller 13, a data driver 14, a scan driver 15, and a power supply 16.

The display panel 11 displays an image in response to a data signal DATA supplied from the data driver 14, a scan signal supplied from the scan driver 15, and power supplied from the power supply 16.

The display panel 11 may include a subpixel SP arranged at each of the intersections of a plurality of gate lines GL and a plurality of data lines DL. The structure of the subpixel SP may vary depending on the type of the light emitting display device 1000.

For example, the subpixels SP may be formed in a top emission method, a bottom emission method, or a dual emission method depending on the structure. The subpixels SP are units that can emit light of their own color with or without a specific type of color filter. For example, the subpixels SP may include a red subpixel, a green subpixel, and a blue subpixel. Alternatively, the subpixel SP may, for example, include a red subpixel, a blue subpixel, a white subpixel, and a green subpixel. The subpixels SP may have one or more different light emitting portions depending on the light emitting characteristics. For example, the blue subpixel and the subpixels emitting light with different colors may have different light emitting portions.

One or more subpixels SP may constitute one unit pixel. For example, one unit pixel may include red, green, and blue subpixels, and the red, green, and blue subpixels may be repeatedly arranged. Alternatively, one unit pixel may include red, green, blue, and white subpixels, and the red, green, blue, and white subpixels may be arranged repeatedly, or the red, green, blue, and white subpixels may be arranged in quads. In an embodiment according to the present disclosure, the color type, arrangement type, arrangement order, or the like of the subpixels may be determined depending on the light emission characteristics, lifespan of the device, device specifications, etc., and are not limited thereto.

The display panel 11 may be divided into a display area (AA: inside a dotted area) where subpixels SP are arranged to display an image, and a non-display area NA around the display area NA. The scan driver 15 may be mounted in the non-display area NA of the display panel 11. In addition, the non-display area NA may include a pad portion PAD including a pad electrode PD.

Here, the display area NA is also called an “active area” and the non-display area NA is also called a “non-active area”.

The image processer 12 may output a data enable signal DE in addition to a data signal DATA supplied from the outside. The image processer 12 may output one or more of a vertical synchronization signal, a horizontal synchronization signal, and a clock signal in addition to the data enable signal DE, but these signals are omitted for convenience of description.

The timing controller 13 may receive a data signal DATA in addition to a driving signal from the image processer 12. The driving signal may include a data enable signal DE. In addition, the driving signal may include a vertical synchronization signal, a horizontal synchronization signal, and a clock signal. The timing controller 13 includes a data timing control signal DDC for controlling the operation timing of the data driver 14 and a gate timing control signal GDC for controlling the operation timing of the scan driver 15 based on the driving signal.

The data driver 14 samples and latches the data signal DATA supplied from the timing controller 13 in response to the data timing control signal DDC supplied from the timing controller 13, converts the resulting data signal DATA into a gamma reference voltage, and outputs the gamma reference voltage.

The data driver 14 may output the data signal DATA through the data lines DL. The data driver 14 may be provided as an integrated circuit IC. For example, the data driver 14 may be electrically connected to the pad electrode PD disposed in the non-display area NA of the display panel 11 through a flexible circuit film (not shown).

The scan driver 15 may output a scan signal in response to the gate timing control signal GDC supplied from the timing controller 13. The scan driver 15 may output a scan signal through the gate lines GL. The scan driver 15 may be implemented in the form of an integrated circuit IC or may be implemented in the display panel 11 in the form of a gate in panel GIP.

The power supply 16 may output a high potential voltage and a low potential voltage for driving the display panel 11. The power supply 16 may supply a high potential voltage to the display panel 11 through a first power line EVDD (driving power line or pixel power line) and supply a low potential voltage to the display panel 11 through a second power line (EVSS) (auxiliary power line or a common power line).

The display panel 11 is divided into a display area AA and a non-display area NA, and includes a plurality of subpixels SP defined by gate lines GL and data lines DL which cross each other in the display area AA to form a matrix.

The subpixels SP may include subpixels that emit at least two colors of light among red light, green light, blue light, yellow light, magenta light, and cyan light. In addition, the subpixels SP may emit their own color with or without a specific type of color filter, but the present disclosure is not necessarily limited thereto. The color type, arrangement type, and arrangement order of the subpixels SP may be determined depending on light emission characteristics, lifespan of the device, and device specifications.

Each of the subpixels SP may include a light emitting portion that emits light and a non-light emitting portion around the light emitting portion.

In the light emitting display device of the present disclosure, the light emitting element is formed on the planarization film. The light emitting portion is divided into a front light emitting portion based on a first element provided on the bottom surface of the recess of the planarization film and a side light emitting portion based on a second element provided on the side of the recess of the planarization film.

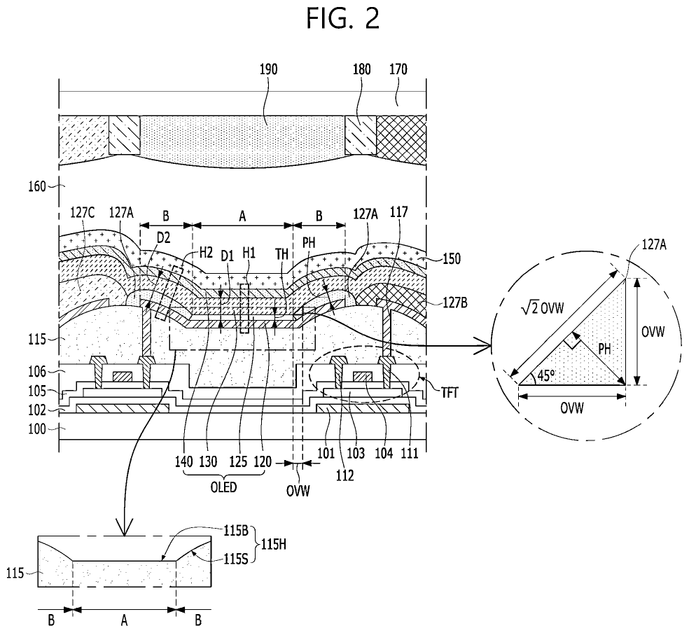

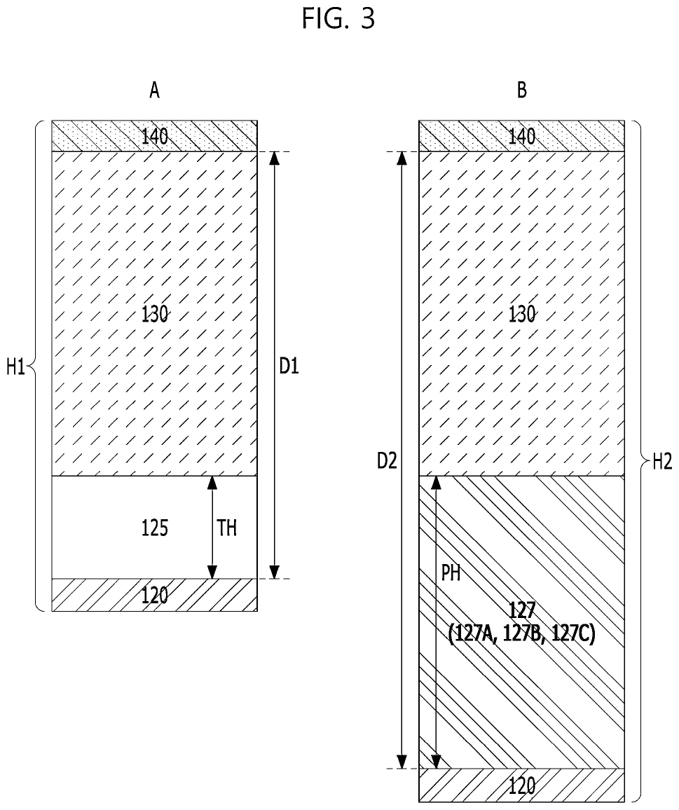

FIG. 2 is a cross-sectional view illustrating a light emitting display device according to an embodiment of the present disclosure, and FIG. 3 is a cross-sectional view illustrating the first element in area A and the second element in area B of FIG. 2.

As shown in FIG. 2, a light emitting display device according to an embodiment of the present disclosure includes a substrate 100 including a plurality of subpixels, a planarization film 115 provided on the substrate 100 and having a recess 115H in each subpixel, a reflective anode 120 provided along the surface of the recess 115H, a transparent electrode 125 provided on the reflective anode 120 disposed on the bottom surface 115B of the recess 115H, patterns 127A, 127B, and 127C overlapping a side surface 115S of the recess 115H with the reflective anode 120 interposed therebetween, an intermediate layer 130 disposed on the patterns 127A, 127B, and 127C, and the transparent electrode, and a cathode 140 disposed on the intermediate layer.

Here, the recess 115H of the planarization film 115 includes a bottom surface 115B and an inclined side surface 115S around the bottom surface 115B. In the light emitting display device of the present disclosure, a recess 115H is disposed in each subpixel.

The planarization film 115 may be provided with a flat surface between the recesses 115H. In this case, the flat surface of the planarization film 115 may be provided at the boundary between the subpixels.

The planarization film 115 is formed to have a sufficient thickness to completely cover the array including the thin film transistor TFT formed below. The thickness of the planarization film 115 may be about 2 μm to about 5 μm. A thickness of 1 μm or more may be left in the area where the recess 115H is disposed not to expose the array including the thin film transistor TFT disposed below. That is, the planarization film 115 with a predetermined thickness is left between the bottom surface of the recess 115H and the lowermost surface of the planarization film 115 to protect the array including the thin film transistor disposed thereunder.

The planarization film 115 may be formed of an organic insulating material. The planarization film 115 is formed of an overcoat material. For example, the planarization film 115 contains at least one of a polymer having a phenol group, an acrylic polymer, an imide polymer, an aryl ether polymer, a fluorine polymer, a p-xylene polymer, a vinyl alcohol polymer, or a styrene polymer. These materials are provided as examples and the planarization film 115 may be formed of other material that maintains organic insulating properties and allows light emitting elements to be uniformly formed on the top thereof.

Each subpixel causes emission of front light from the light emitting element (OLED) in the first region A where the bottom surface 115B of the recess 115H is disposed, and causes emission of side light along with light reflection on the top surface of the reflective anode 120 formed along an inclined side surface 115S of the second region B where the side surface 115S is disposed. Light is reflected from the top surface of the reflective anode 120 formed along the side surface 115S.

The first region A and the second region B may be divided into a front light emitting portion and a side light emitting portion.

The organic light emitting element (OLED) including the reflective anode 120, the transparent electrode 125, the intermediate layer 130, and the cathode 140 is provided on the planarization film 115 to emit light upward.

The reflective anode 120 may be formed of a metal or metal alloy with high reflection efficiency and include a single layer or multiple layers of any one selected from the group consisting of silver (Ag), aluminum (Al), copper (Cu), molybdenum (Mo), titanium (Ti), nickel (Ni), chromium (Cr), or tungsten (W), or an alloy thereof. A lower transparent electrode may be further provided below the reflective anode 120. In this case, the lower transparent electrode and the reflective anode 120 may have the same width as each other. The cathode 140 may be internally reflected to cause resonance within the light emitting element (OLED) and may be formed as a thin transmissive metal or transparent electrode that allows light to pass therethrough depending on resonance conditions. The cathode 140 is formed of silver (Ag), aluminum (Al), magnesium (Mg), calcium (Ca), ytterbium (Yb), strontium (Sr), or an alloy thereof, or a transparent conductive material such as indium-tin-oxide (ITO) or indium zinc oxide (IZO).

Each component will be described as follows. As shown in FIGS. 2 and 3, the first region A includes the reflective anode 120, the transparent electrode 125, the intermediate layer 130, and the cathode 140 provided in that order on the bottom surface 115B of the recess 115H of the planarization film 115 to form the first element H1. In the first element H1, when light is emitted from the intermediate layer 130 between the reflective anode 120 and the cathode 140, the emitted light is radiated randomly and is exposed to the inner surface of the reflective anode 120, and undergoes repeated reflection and resonance at the first resonance distance D1 between the inner surface of the reflective anode 120 and the inner surface of the cathode 140, and front light is finally emitted above the cathode 140. Meanwhile, the thickness of the transparent electrode 125 in the first element H1 may be adjusted to the optimal cavity corresponding to the wavelength emitted in each subpixel. Accordingly, the transparent electrode 125 may have a different thickness for each subpixel.

The intermediate layer 130 may include a light emitting layer, a hole injection layer and a hole transport layer disposed below the light emitting layer, and an electron transport layer and an electron injection layer disposed above the light emitting layer. The intermediate layer 130 may be provided with a plurality of light emitting stacks divided by the charge generation layer. The intermediate layer 130 of each subpixel may include a stack structure only including a light emitting layer that emits white light, or may include a light emitting layer that emits different color light so as to emit light with different colors.

As shown in FIGS. 2 and 3, the second region B includes a reflective anode 120, patterns (127: 127A, 127B, 127C), an intermediate layer 130, and a cathode 140 provided in this order on the side surface 115S of the planarization film 115 to form the second element H2.

Here, the pattern 127 does not overlap the first region A and overlaps the second region B in each subpixel. The pattern 127 may have different thicknesses for each subpixel and may be provided as a first pattern 127A, a second pattern 127B, and a third pattern 127C. Here, each of the first to third patterns 127A, 127B, and 127C may surround the first region A. In addition, the first to third patterns 127A, 127B, and 127C may have different thicknesses depending on the color of light emitted from the corresponding subpixel. The first to third patterns 127A, 127B, and 127C may function as banks that expose the first region A, which is the front light emitting portion. The first to third patterns 127A, 127B, and 127C may be formed of the same material or may be formed of different materials. Meanwhile, the bank generally uses an inner opening surrounded by the bank as a light emitting portion, but the light emitting display device of the present disclosure also uses the first to third patterns 127A, 127B, and 127C as resonance paths, so that the second region B where the first to third patterns 127A, 127B, and 127C are disposed can be used for light emission.

To transmit light within the second element H2, the first to third patterns 127A, 127B, and 127C may be formed of a transparent organic material. Alternatively, the first to third patterns 127A, 127B, and 127C may be formed of a colored organic material to emit light with the same color in the second region B as the light of the same color as the light passing through the color conversion layer 190 on the counter substrate 170 of the first region A. In this case, the first to third patterns 127A, 127B, and 127C may be formed of a color filter material.

The patterns 127A, 127B, and 127C may be thinner than the color conversion layer 190 of the counter substrate 170 to maximize or increase side light efficiency from the side surface 115S of the recess 115H.

The side surface 115S of the recess 115H of the second region B is inclined at an obtuse angle with respect to the top surface of the substrate 100, so that the surface area of the side surface 115S of the recess 115H of the second region B is greater than that of the top surface of the substrate 100 in the second region B and thus improves luminous efficacy in the same effective area through side light-emission. The side surface 115S of the recess 115H may form an internal angle of greater than 90° and not greater than 170° with the bottom surface 115B. In one embodiment of the present disclosure, more preferably, the internal angle between the side surface 115S and the bottom surface 115B of the recess 115H is greater than 95° and smaller than 150° to increase luminous efficacy in the limited surface area of the second region B.

The reflective anode 120 is exposed from the transparent electrode 125 on the side surface 115S of the recess 115H and has an effect of reflecting light generated in the intermediate layer 130 on the side 115S of the recess 115H.

The patterns 127 127A, 127B, 127C may overlap the edge of the transparent electrode 125 provided on the bottom surface 115B of the recess 115H and contact the top surface of the reflective anode 120.

Meanwhile, the example shown in FIG. 2 shows a case where the first pattern 127A forms an angle of 45° with a virtual horizontal plane passing through the second region B. In this case, the internal angle between the side surface 115S and the bottom surface 115B of the recess 115H may be 135°. As can be seen from the enlarged view on the right side of FIG. 2, the length of the side of the first pattern 127A corresponds to \sqrt{2}OVW with respect to the length OVW projected on the substrate 100 of the first pattern 127A. This means that an area larger than the surface area of the substrate 100 is used for light emission in the second region B where the pattern 127A is disposed. In addition, the light emitting display device of the present disclosure not only emits light in the XY plane in the first region A, but also emits light in the three-dimensional area of XYZ on the side surface of the second region B, thereby maximizing or increasing luminous efficacy in the same area. For example, the internal angle between the side surface 115S and the bottom surface 115B of the recess 115H shown in FIG. 2 is 135°. The internal angle is changed within an obtuse angle greater than 90° and not greater than 170°.

In the example shown in FIG. 2, the thickness PH of the first pattern 127A corresponds to \sqrt{2}OVW/2 The thickness of the first pattern 127A used for resonance in the second region B is formed on the reflective anode 120 inclined at an obtuse angle with respect to the bottom surface of the recess 115H and thus is shorter than the vertical thickness OVW of the first pattern 127A.

In the second element H2, when light is emitted from the intermediate layer 130 between the reflective anode 120 and the cathode 140, the emitted light is radiated randomly, repeatedly undergoes reflection and resonance at the second resonance distance D2 between the inner surface of the reflective anode 120 and the inner surface of the cathode 140, and is finally emitted through the surface of the cathode 140. Here, light is randomly radiated from the intermediate layer 130 of the second element H2, but the side surface 115S of the recess 115H where the reflective anode 120 is formed is directed towards the recess 115H. Therefore, light undergoes repeatedly reflection and resonance at the second resonance distance D2 between the inner surface of the reflective anode 120 and the inner surface of the cathode 140, and is finally emitted through the side surface of the inclined cathode 140. The light emission angle of the light entering the surface of the reflective anode 120 along the side surface 115S of the inclined recess 115H may be determined to be symmetrical to the incident angle formed with the normal line of the reflective anode 120.

A capping layer 150 may be further provided on the top surface of the cathode to increase light emission efficiency from the light emitting device (OLED) including the first element H1 in the first region A and the second element H2 in the second region B and to protect the cathode 140.

Each subpixel may be provided with a color conversion layer 190 on the capping layer 150 to emit light of a predetermined color. At this time, the intermediate layer 130 may emit white light, but the light emitting display device of the present disclosure is not limited thereto. For example, the intermediate layer 130 selectively includes a red light emitting layer, a green light emitting layer, and a blue light emitting layer for each subpixel to emit light of the color of the corresponding pixel. In this case, the intermediate layer 130 may overlap the color conversion layer 190. In some cases where the intermediate layer 130 includes a color light emitting layer for each subpixel, the color conversion layer 190 may be omitted.

The color conversion layer 190 may be formed on a counter substrate 170 facing the substrate 100, as shown in FIG. 2, and the color conversion layer 190 on the counter substrate 170 and the uppermost surface of the substrate 100 may face each other with a filler 160 interposed therebetween.

In the example shown in FIG. 2, the uppermost layer on the substrate 100 is provided as the capping layer 150, but the present disclosure is not limited thereto.

The light emitting display device of the present disclosure is not limited to the case where the counter substrate 170 is provided, and may include any configuration in which the color conversion layer 190 is provided on any component above the cathode 140 from which light is emitted.

In addition, a light blocking layer 180 may be further provided between the color conversion layers 190 at the boundary of adjacent subpixels. The light blocking layer 180 prevents color mixing between adjacent subpixels. In some cases, the light blocking layer 180 is omitted and the color conversion layers 190 for transmitting light of different wavelengths corresponding to the boundaries of adjacent subpixels may replace the light blocking layer.

A protective film or encapsulation layer may be further provided on the capping layer 150. In some cases, the counter substrate 170 and/or the filler 160 may be omitted and the color conversion layer 190 may be formed directly on the capping layer 150 or on the encapsulation layer.

A touch sensor may be further provided on the counter substrate 170 or the encapsulation layer.

The substrate 100 and the counter substrate 170 are base substrates and may be formed of glass or plastic. For example, the first substrate SUB1 may be formed of a plastic material such as polyimide (PI), polyethylene terephthalate (PET), polyethylene naphthalate (PEN), or polycarbonate (PC), and may be flexible.

Circuit elements including various signal lines, thin film transistors (TFTs), storage capacitors, and the like may be formed in respective subpixels on the substrate 100. The signal lines include a gate line, a data line, a first power line (not shown) (EVDD, driving power line or pixel power line), a second power line (not shown) (EVSS, auxiliary power line or common power line), and a reference line, and the like, and the thin film transistor TFT may include a driving thin film transistor, a switching thin film transistor, a sensing thin film transistor and the like.

A light-shielding layer 101 may be disposed on the substrate 100. The light-shielding layer 101 may overlap the thin film transistor TFT. For example, the light-shielding layer 101 may overlap the active layer ACT of the thin film transistor (TR), and in particular, may overlap a channel region of the active layer ACT on a plane. The light-shielding layer 101 may serve to block external light from entering the active layer ACT.

A buffer layer 102 may be disposed on the substrate 100 so as to cover the light-shielding layer 101. The buffer layer 102 may be formed as a single layer or a stack including a plurality of inorganic films. For example, the buffer layer 102 may be a single layer including a silicon oxide film (SiOx), a silicon nitride film (SiNx), or a silicon oxynitride film (SiOxNy). In addition, the buffer layer 102 may be formed of multiple layers in which at least two layers of a silicon oxide (SiOx) film, a silicon nitride (SiNx) film, and a silicon oxynitride (SiOxNy) film are stacked. The buffer layer 102 may be formed on the entire top surface of the substrate 100 to block ions or impurities diffusing from the substrate 100 and to block moisture penetrating into the organic light emitting element (OLED) through the substrate 100.

A thin film transistor TFT and a storage capacitor may be disposed on the buffer layer 102. The thin film transistor TFT may be disposed in each of a plurality of subpixels on the buffer layer 102. For example, the thin film transistor TFT includes an active layer 103, and a gate electrode 104, a source electrode 112, and a drain electrode 111 that overlap the active layer 103 with the gate insulating film 105 interposed therebetween.

The active layer 103 of the thin film transistor TFT may be formed of a silicon or oxide semiconductor material on the buffer layer 102. The active layer 103 may include a channel region overlapping the gate electrode 104 and source/drain regions connected to each of the source electrode 112 and the drain electrode 111.

A gate insulating layer 105 may be formed on the active layer 103. The gate insulating film 105 may be disposed on the channel region of the active layer 103 and may function to insulate the active layer 103 and the gate electrode 105. The gate insulating film 105 may be formed of an inorganic insulating material, for example, a silicon oxide film (SiOx), a silicon nitride film (SiNx), a silicon oxynitride film (SiOxNy), or a multilayer film thereof.

A gate electrode 104 may be formed on the gate insulating film 105. The gate electrode 104 may face the active layer 103 with the gate insulating film 105 interposed therebetween. In addition, the gate electrode 104 may include a single layer or multiple layers containing any one selected from the group consisting of copper (Cu), molybdenum (Mo), aluminum (Al), chromium (Cr), gold (Au), titanium (Ti), nickel (Ni), neodymium (Nd), tantalum (Ta), tungsten (W) and an alloy thereof.

An interlayer insulating film 106 covering the gate electrode 104 may be formed on the buffer layer 102. In addition, the interlayer insulating film 106 may function to protect at least one electrode and the active layer 103 of the thin film transistor TFT. The interlayer insulating film 106 may be formed of an inorganic insulating material. For example, the interlayer insulating film 106 may be formed as a silicon oxide film (SiOx), a silicon nitride film (SiNxa), a silicon oxynitride film (SiOxNy), or a multilayer film thereof.

A source electrode 112 and a drain electrode 111 may be formed on the interlayer insulating film 106. To bring the active layer 103 into contact with the source electrode 112 and the drain electrode 111, the corresponding area of the interlayer insulating film 106 may be removed. For example, the source electrode 112 and the drain electrode 111 may contact the active layer 103 through a contact hole penetrating the interlayer insulating layer 106 and the gate insulating layer 105 and may be electrically connected to the active layer 103.

The source electrode 112 and the drain electrode 111 may be formed of a single layer or multiple layers. When the source electrode 112 and the drain electrode 111 are a single layer, they may be formed of any one selected from the group consisting of the group consisting of molybdenum (Mo), aluminum (Al), chromium (Cr), gold (Au), titanium (Ti), nickel (Ni), neodymium (Nd) and copper (Cu), or an alloy thereof. In addition, when the source electrode 112 and the drain electrode 111 are provided as multiple layers, they may be a double layer of molybdenum/aluminum-neodymium, molybdenum/aluminum, titanium/aluminum, or copper/moly titanium. Alternatively, the source electrode 112 and the drain electrode 111 may be formed of a triple layer of molybdenum/aluminum-neodymium/molybdenum, molybdenum/aluminum/molybdenum, titanium/aluminum/titanium, or molytitanium/copper/molytitanium, but are not limited thereto. The first and second source/drain electrodes SD1 and SD2, and the auxiliary power electrode APE are formed of multiple layers containing any one selected from the group consisting of molybdenum (Mo), aluminum (Al), chromium (Cr), gold (Au), titanium (Ti), nickel (Ni), neodymium (Nd), or copper (Cu), or an alloy thereof.

Meanwhile, an example in which the thin film transistor TFT is provided on each subpixel is illustrated in FIG. 2, but each subpixel may include a plurality of thin film transistors TFT, and the plurality of thin film transistors TFT include active layers disposed in at least two different layers and are provided in different layered structures. In this case, the thin film transistors of different layers may have different mobility or different transmission characteristics.

The planarization film 115 having the recess 115H is disposed on the thin film transistor TFT. The planarization film 115 may be formed to cover the thin film transistor TFT. The planarization film 115 protects the thin film transistor TFT. The planarization film 115 may further include an inorganic passivation layer as a lower layer. In this case, the inorganic passivation layer is formed of an inorganic insulating material and may, for example, include a silicon oxide film (SiOx), a silicon nitride film (SiNx), a silicon oxynitride film (SiOxNy), or a multilayer film thereof.

As described above, the first element H1 is formed on the bottom surface 115B of the recess and the second element H2 is formed on the side surface 115S of the recess.

The reflective anode 120 is continuous in the first region A and the second region B, and the intermediate layer 130 and the cathode 140 are also continuous in the first region A and the second region B. Therefore, the first and second elements H1 and H2 can be driven with the same electric field.

The first element H1 and the second element H2 are components between the reflective anode 120 and the intermediate layer 130, and have different transparent electrodes 125 and patterns 127: 127A, 127B, and 127C, and thus have different resonance conditions.

In at least one of the subpixels, the total thickness of the intermediate layer 130 and the transparent electrode 125 between the reflective anode 120 and the cathode 140 on the bottom surface 115B of the recess 115H of the planarization film 115 is the first resonance distance (D1, first thickness), and the total thickness of the patterns 127 127A, 127B, 127C and the intermediate layer 130 between the reflective anode 120 and the cathode 140 on the side surface 115S of the recess 115H of the planarization film 115 is the second resonance distance (D2, second thickness). Each of the first thickness D1 and the second thickness D2 may be independently proportional to the wavelength transmitted by the color conversion layer 190 disposed on the counter substrate 170.

White light may be emitted from the intermediate layer 130, and for example, the color conversion layer 190 may include a blue filter, a green filter, or a red filter. When the color conversion layer 190 includes a blue filter, its center wavelength may be set to 460 nm. When the color conversion layer 190 includes a green filter, the center wavelength thereof may be set to 530 nm. When the color conversion layer 190 includes a red filter, the center wavelength thereof may be set to 620 nm.

Resonance conditions are shown in Equation 1 below.

2nd=mλ (wherein n is a refractive index, d is a thickness of the area where resonance occurs, m is an integer, and λ is a wavelength corresponding to resonance) [Equation 1]

The first element H1 and the second element H2 each follow resonance conditions and n is the average refractive index of the intermediate layer 130. For example, the average refractive index of the intermediate layer 130 may be 1.7 to 2.0.

M equal to 1, 2, and 3 may be referred to as “first order”, “second order” and “third order”, respectively, and the resonance distances D1 and D2 of the first and second elements H1 and H2 correspond to the thickness d of the area where the resonance of Equation 1 above occurs depending on the wavelength at which resonance occurs and may be calculated as mλ/2n. The resonance distance follows Table 1 below. In Table 1, the average refractive index of the intermediate layer 130 was calculated as 1.8.

TABLE 1

| | First order | Second order | Third order |
|---|---|---|---|
| | (m = 1) | (m = 2) | (m = 3) |
| | resonance | resonance | resonance |
| | distance (nm) | distance (nm) | distance (nm) |
| Blue (center | 128 | 256 | 384 |
| wavelength 460 nm) | | | |
| Green (center | 147 | 294 | 441 |
| wavelength 530 nm) | | | |
| Red (center | 172 | 344 | 516 |
| wavelength 620 nm) | | | |

Since the intermediate layer 130 is common to the first and second resonance distances D1 and D2 of the first and second elements H1 and H2, the thickness of the first element H1 can be adjusted to the thickness corresponding to the m^{th} order of the corresponding wavelength by adjusting the thickness of the transparent electrode 125, and the thickness of the second element H2 can be adjusted to the thickness corresponding to the m order of the corresponding wavelength by adjusting the thickness of the patterns (127: 127A, 127B, 127C). In each subpixel, the first and second elements H1 and H2 may use resonance distances depending on the same m order or may use resonance distances depending on different orders. FIG. 3 shows an example using an order larger than the second resonance distance D1 of the first element H1 by thickening the second resonance distance D2 of the second element H2. The present disclosure is not limited to the example in FIG. 3. The first element H1 and the second element H2 may use the same order. Among the first element H1 and the second element H2, the order of the first element H1 may be greater than that of the second element H2.

In the light emitting display device of the present disclosure, as the thickness of the planarization film 115 increases, the area where the recess 115H is provided may be increased and thus the side mirror effect can be improved.

The patterns 127 127A, 127B, 127C may contain a polyimide-based polymer, a polyamide-based polymer, or acrylate-based polymer. The patterns 127 127A, 127B, 127C may be formed of an organic polymer material with an average refractive index lower than that of the intermediate layer 180. Accordingly, the light emitted from the intermediate layer 180 may be refracted and reflected on the surface of the patterns 127 127A, 127B, 127C due to the difference in refractive index at the interface. For example, the average refractive index of the intermediate layer 180 may be 1.8 to 1.9, and the refractive index of the patterns 127 127A, 127B, 127C may be 0.1 to 0.5 which is lower than the average refractive index of the intermediate layer 180.

When the patterns 127 127A, 127B, 127C include the same material as the color conversion layer 190, a color pigment may be further included in the polymer material described above.

The transparent electrode 125 may be formed of ITO (indium tin oxide), IZO (indium zinc oxide), or ITZO (indium tin zinc oxide). The transparent electrode 125 may have the same thickness in each subpixel. Alternatively, the transparent electrode 125 may have different thicknesses in subpixels that emit light of different colors. When the transparent electrode 125 has different thicknesses in the subpixels, the thickness TH of the transparent electrode 125 may be adjusted so that the first elements H1 of the different subpixels have the same order or one or more of the first elements H1 have different orders. When subpixels have different orders, for example, the thickness TH of the transparent electrode 125 of each subpixel is adjusted such that the blue subpixel has a first order, and the green and red subpixels have a second order. The thickness TH of the transparent electrode 125 may be adjusted to vary the order of each subpixel depending on the color temperature of the light emitting display device.

The patterns (127: 127A, 127B, 127C) adjust the resonance distance of the second element H2 and the thickness (PH) of the patterns (127: 127A, 127B, 127C) in the second element H2 may be adjusted such that the second elements H2 of different subpixels have the same order or one or more of the second elements H2 have different orders. Since the blue subpixel, green subpixel, and red subpixel have different wavelengths, even if the same order is applied to each subpixel for the second elements H2, the thickness TH of the patterns (127: 127A, 127B, 127C) may be different. In addition, assuming that the second element H2 has different orders for each subpixel, for example, the thickness PH of the patterns 127 (127A, 127B, 127C) of each subpixel may be adjusted such that the blue subpixel is set to have a first order and the green subpixel and red subpixel are set to have a second order.

The first element H1 has a direct light emission effect compared to the second element H2 and contains the metal oxide component of the transparent electrode 125. The transparent electrode 125 may also be used for reflection in the resonance path, so that the first element H1 may have better luminous efficacy than the second element H2.

In some cases, the thickness TH of the transparent electrode 125 may be proportional to the thickness of the patterns 127 (127a, 127b, 127c) of the same subpixel. Since the thickness of the first element H1 is proportional to the second element H2 in the same subpixel, the efficiency deviation can be reduced.

In addition, the transparent electrode 125 on the reflective anode 120 has effects of reducing interfacial resistance at the interface where the transparent electrode 125 contacts the intermediate layer 130 and thus of lowering the barrier to hole injection.

The first resonance between the reflective anode 120 and the cathode 140 on the bottom surface 115B of the recess 115H of the planarization film 115, and the second resonance between the reflective anode 120 and the cathode 140 at the side surface of 115B of the recess 115H of the planarization film 115 may have different orders or the same order. The first resonance and the second resonance may be adjusted independently.

Meanwhile, the light emitting display device of the present disclosure may further include a light blocking layer 180 between adjacent color conversion layers 190 to prevent light leakage from adjacent subpixels when refracted light, rather than direct light, is emitted from the reflective anode 120 formed along the inclined side surface of the recess 115S of each subpixel. The light blocking layer 180 may contain a polymer material containing a black pigment or light blocking metal particles.

The filler 160 covers the capping layer 150 to block external moisture or oxygen from flowing into the light emitting element (OLED). The filler 160 may be formed of a material transmitting light. For example, the filler 160 may be formed of an organic material. For example, the filler 160 may be formed of a silicon-based organic material, an epoxy-based organic material, or a mixture of a silicon-based organic material and an epoxy-based organic material.

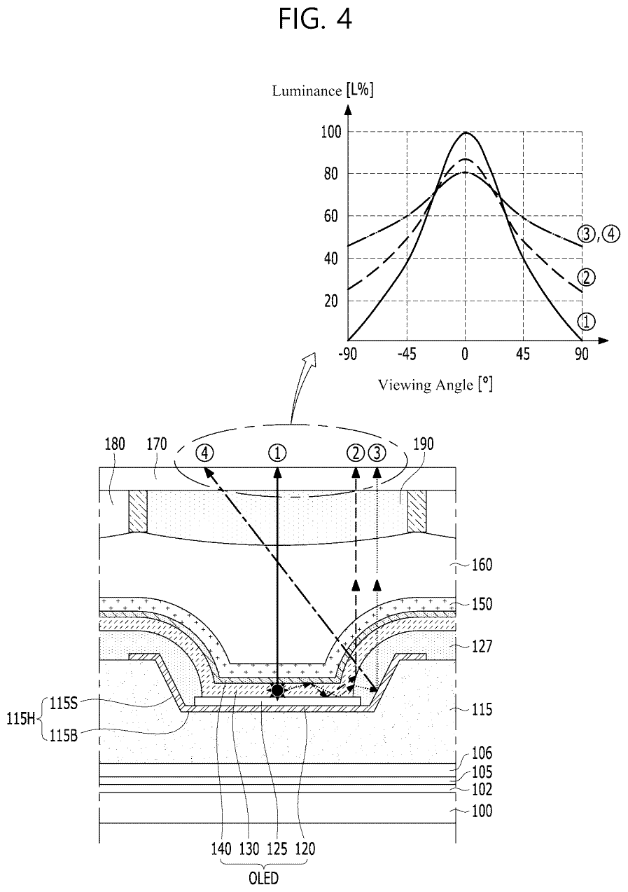

The light emission effect of the light emitting display device of the present disclosure will be described with reference to FIG. 4.

FIG. 4 is a graph showing first to fourth light generation and luminance characteristics as a function of viewing angle in the light emitting device according to an embodiment of the present disclosure.

As shown in FIG. 4, each subpixel of the light emitting display device of the present disclosure generates four types of light, including first to fourth lights (\textcircled{1}, \textcircled{2}, \textcircled{3}, \textcircled{1}). In each subpixel, the first element H1 emits light through the cavity on the bottom surface 115B of the recess 115H and this light is a front light travelling upward, which is defined as the first light \textcircled{1}. In this case, the first light (\textcircled{1}) is emitted as the light reflected upward from the reflective anode 120 and the light reflected upward from the transparent electrode 125 are doubled due to constructive interference and light with greatest luminance efficiency is emitted in the subpixel is emitted.

In addition, the light totally internally reflected in the first element H1 is refracted from the surface of the pattern 127 due to the difference in refractive index between the pattern 127 and the intermediate layer 130 and second light (\textcircled{2}) is emitted toward the front in the same vertical direction as the first light (\textcircled{1}).

Since the first light \textcircled{1} and the second light \textcircled{2} mainly use the intermediate layer 130 as a main light path, they have a microcavity effect of the intermediate layer 130. Therefore, the first light \textcircled{1} and the second light \textcircled{1} have excellent light emission characteristics to the front. However, since the first light (\textcircled{1}) and the second light (\textcircled{2}) have cavity characteristics with high efficiency for a specific wavelength, the luminance characteristics may deteriorate when viewed at a viewing angle different from the front.

The light passing through the pattern 127 includes third light \textcircled{3}, which is emitted from the intermediate layer 130, passes through the pattern 127 and is emitted from the reflective anode 120 toward the front and fourth light (\textcircled{4}), which is refracted from the side surface 115S of the recess 115H toward the recess 115H within the subpixel and is refracted and emitted at an angle other than perpendicular to the surface of the substrate 100.

Since the third light (\textcircled{3}) and the fourth light (\textcircled{4}) do not generate light through the pattern 127 and simply function to transmit light, thus having low light efficiency compared to the first light (\textcircled{1}) and the second light (\textcircled{2}) having light path in the intermediate layer 130. In addition, the third light \textcircled{3} and the fourth light 4 have non-cavity characteristics based on the transmittivity of the pattern 127. Therefore, the third light (\textcircled{3}) and the fourth light (\textcircled{4}) have the equal transmission characteristics even though the viewing angles of the pattern 127 are different, thus avoiding a great decrease in luminance even at viewing angles other than the front, compared to the first light (\textcircled{1}) and the second light (\textcircled{2}).

Accordingly, the light emitting display device of the present disclosure improves luminous efficacy at the front through the first light (\textcircled{1}) and the second light (\textcircled{2}), and reduces the change in luminance caused by change in viewing angle through the third light (\textcircled{3}) and the fourth light (\textcircled{4}). Therefore, the light emitting display device of the present disclosure improves light efficiency and reduces visibility of changes depending on changes in the user's viewing angle.

Hereinafter, the structure applied to the intermediate layer 130 of the present disclosure will be described.

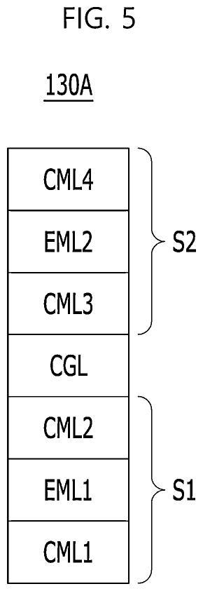

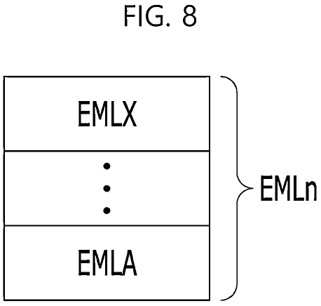

FIGS. 5 to 7 are cross-sectional views showing intermediate layers included in the light emitting display device of the present disclosure according to different embodiments. FIG. 8 is a diagram illustrating an example of a multilayer configuration of the light emitting layer in the intermediate layer.

As shown in FIG. 5, the intermediate layer 130A of the light emitting display device of the present disclosure according to one embodiment includes a first common layer (CML1), a first light emitting layer (EML1), a second common layer (CML2), a charge generation layer (CGL), a third common layer (CML3), a second emitting layer (EML2), and a fourth common layer (CML4) formed sequentially on the transparent electrode 125 and the patterns 127 127A, 127B, 127C.

The first and third common layers CML1 and CML3 may include a hole transport layer, a hole transport auxiliary layer, and an electron blocking layer. The first common layer CML1 may further include a hole injection layer below the hole transport layer.

The second and fourth common layers CML2 and CML4 may include a hole blocking layer, an electron transport layer, and an electron transport auxiliary layer. The fourth common layer CML4 contacting the cathode 140 may further include an electron injection layer at the interface contacting the cathode 140.

Here, the first stack S1 and the second stack S2 may be distinguished based on the charge generation layer CGL.

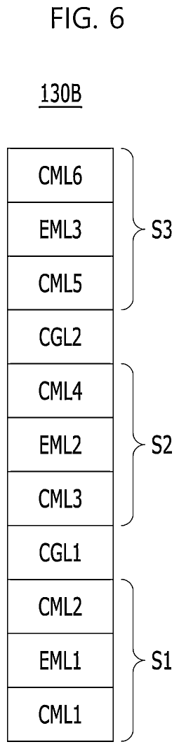

As shown in FIG. 6, the intermediate layer 130A of the light emitting display device according to one embodiment of the present disclosure includes a first common layer (CML1), a first light emitting layer (EML1), a second common layer (CML2), a first charge generating layer (CGL1), a third common layer (CML3), a second emitting layer (EML2), a fourth common layer (CML4), a fifth common layer (CML5), and a sixth common layer (CML6) sequentially formed on the transparent electrode 125 and the patterns 127 127A, 127B, 127C.

The embodiment of FIG. 6 further includes a second charge generation layer CGL2 and a third stack S3 compared to the embodiment of FIG. 5, and description of the same configuration will be omitted.

The fifth common layer CML5 may include a hole transport layer, a hole transport auxiliary layer, and an electron blocking layer.

The sixth common layer CML6 may include a hole blocking layer, an electron transport layer, an electron transport auxiliary layer, and the like. The sixth common layer CML6 contacting the cathode 140 may further include an electron injection layer at the interface contacting the cathode 140.

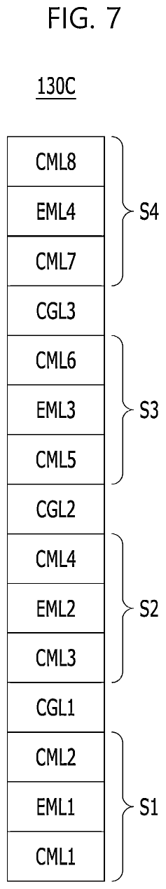

In some cases, as shown in FIG. 7, a third charge generation layer CGL3 and a fourth stack S4 may be further included compared to the embodiment of FIG. 6. Description of the same configuration as the embodiment of FIG. 6 will be omitted.

The seventh common layer CML7 may include a hole transport layer, a hole transport auxiliary layer, an electron blocking layer and the like.

The eighth common layer CML8 may include a hole blocking layer, an electron transport layer, an electron transport auxiliary layer, and the like. The eighth common layer CML6 contacting the cathode 140 may further include an electron injection layer at the interface contacting the cathode 140.

Meanwhile, in the above-described embodiments, as shown in FIG. 8, at least one light emitting layer EMLn may be formed by stacking two or more light emitting layers (EML1, . . . , EMLX).

Each stack S1, S2, S3 or S4 may include at least two light emitting layers of the same color.

In the embodiments of FIGS. 5 to 7, light emitting layers (EML1/EML2 or EML1/EML2/EML3 or EML1/EML2/EML2/EML4) overlapping in the corresponding subpixel may be the same color light emitting layers in each stack S1, S2, S3 or S4. For example, the blue subpixel may include all blue light emitting layers in each stack, the green subpixel may include all green light emitting layers in each stack, and the red subpixel may include all red subpixels in each stack. In this case, the color filter on the counter substrate 170 may be omitted.

In each embodiment of FIGS. 5 to 7, to emit white light in the intermediate layer 130, the display may include the stack including the blue light emitting layer and another stack including a red light emitting layer and a green light emitting layer, or including a yellow green light emitting layer, or including a red light emitting layer, a yellow-green light emitting layer and a green light emitting layer stacked in this order. The blue light emitting layer, the red light emitting layer, the green light emitting layer, and the yellow-green light emitting layer may be any one of a fluorescent light emitting layer and a phosphorescent light emitting layer, or may be a mixed light emitting layer containing a mixture of a fluorescent material and a phosphorescent material.

When the light emitting layer (EMLn) in one of the stacks (S1, S2, S3, S4) of the intermediate layer 130 includes a plurality of light emitting layers (EMLA, . . . , EMLX), as shown in FIG. 8, the light emitting layers may be arranged sequentially from the bottom to the top, or conversely, from short wavelength to long wavelength.

FIGS. 5 to 7 show examples of two stacks, three stacks, and four stacks, respectively, but the light emitting display device of the present disclosure is not limited thereto and the light emitting display may have a single stack structure including one light emitting layer or may have a configuration of five or more stacks.

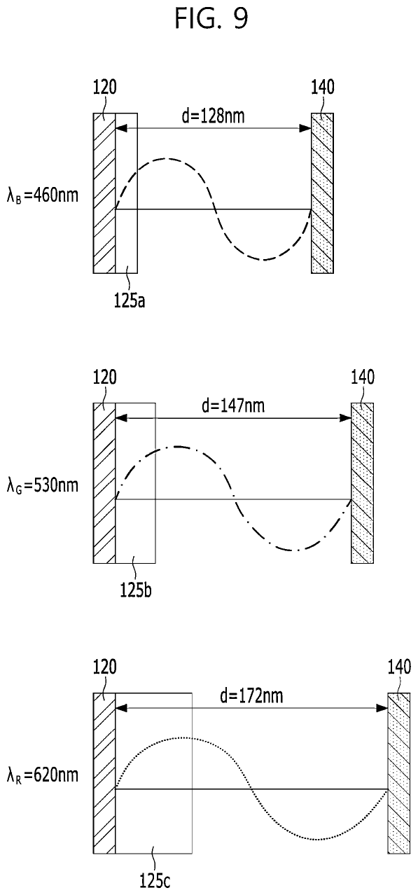

FIG. 9 is a diagram showing constructive interference between the reflective anode and the cathode for each wavelength of the first element.

In FIG. 9, the cathode 140 may use a reflection-transmission electrode to increase microcavity characteristics for a specific wavelength.

FIG. 9 shows an example in which the transparent electrodes 125a, 125b, and 125c between the reflective anode 120 and the cathode 140 in each subpixel emitting light with different wavelengths have different thicknesses depending on the light emission characteristics. In this case, the cathode 140 may be a reflective and transparent electrode. The intermediate layer 130 of each subpixel may emit white light and the color conversion layer 190 may be disposed on the top of the light emitting element to vary the light emission characteristics depending on the transmission characteristics of the color conversion layer 190, or the emission characteristics may vary depending on the emission color of the light emitting layer included in the intermediate layer 130.

When the central wavelengths of blue, green, and red are 460 nm, 530 nm, and 520 nm, and the resonance condition according to the first order is obtained, the constructive interference distance between the reflective anode 120 and the cathode 140 changes in proportion to the wavelength. As shown in Table 1 and FIG. 9, when the average refractive index of the intermediate layer 130 is set to 1.8, the thickness (d) indicating the microcavity of each wavelength may be calculated as a value of λ/2n. That is, the thickness between the reflective anode 120 and the cathode 140 in the blue subpixel is 128 nm, the thickness between the reflective anode 120 and the cathode 140 in the green subpixel is 147 nm, and the thickness between the reflective anode 120 and the cathode 140 in the red subpixel is 172 nm.

In the example of FIG. 9, the thickness between the reflective anode 120 and the cathode 140 for each wavelength is adjusted in the first order, but is not limited thereto. When multiple stacks are required to secure a predetermined efficiency of a light emitting display device, the order for each wavelength can be increased.

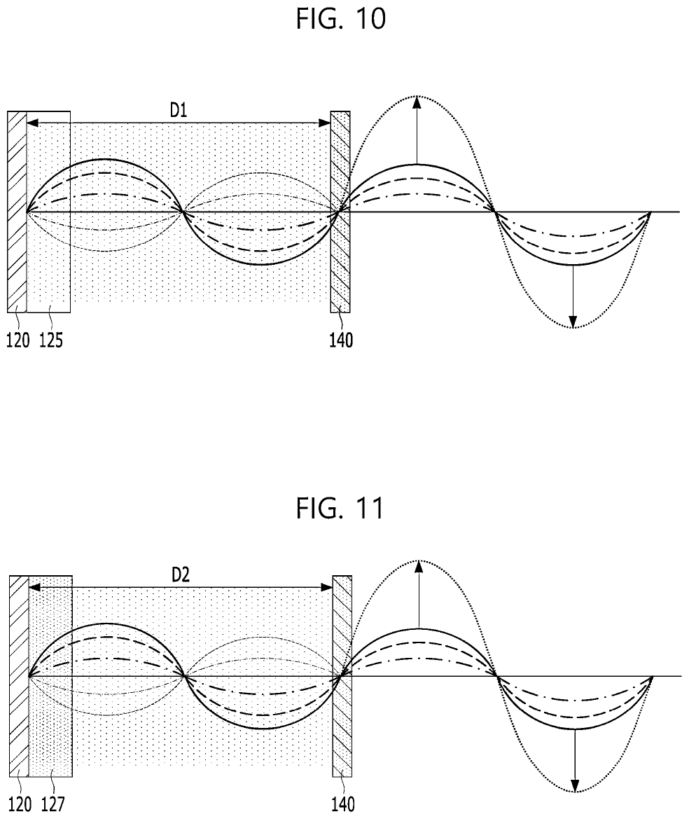

FIG. 10 is a diagram showing the principle of light emission by constructive interference between the reflective anode and cathode of the first element (see H1 in FIG. 2), and FIG. 11 is a diagram showing the principle of light emission by constructive interference between the reflective anode and cathode of the second element (see H2 in FIG. 2).

As shown in FIG. 10, the first element is provided with a transparent electrode 125 in contact with the reflective anode 120. Resonance between the reflective anode 120 and the cathode 140 is repeated. As a result, the efficiency of light of a specific wavelength finally emitted from the cathode 140 is high due to the constructive interference effect.

As shown in FIG. 11, the second element is provided with a pattern 127 in contact with the reflective anode 120, and the resonance between the reflective anode 120 and the cathode 140 is repeated. Finally, the efficiency of light with a specific wavelength that undergoes constructive interference emitted from the cathode 140 is high through the constructive interference effect.

However, since constructive interference occurs between the transparent electrode 125 and the cathode 140 in the first element due to reflection and interference effects, the first element may have higher luminous efficacy than the second element.

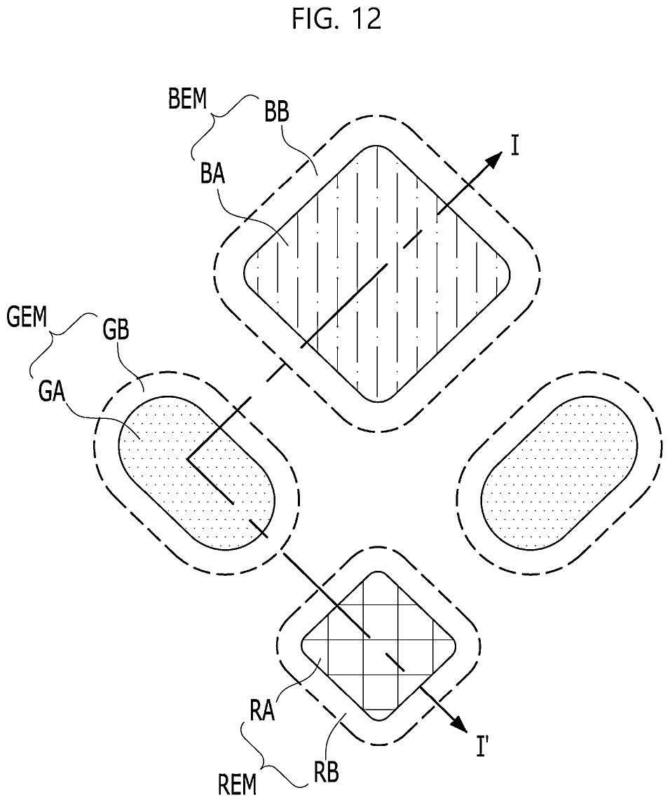

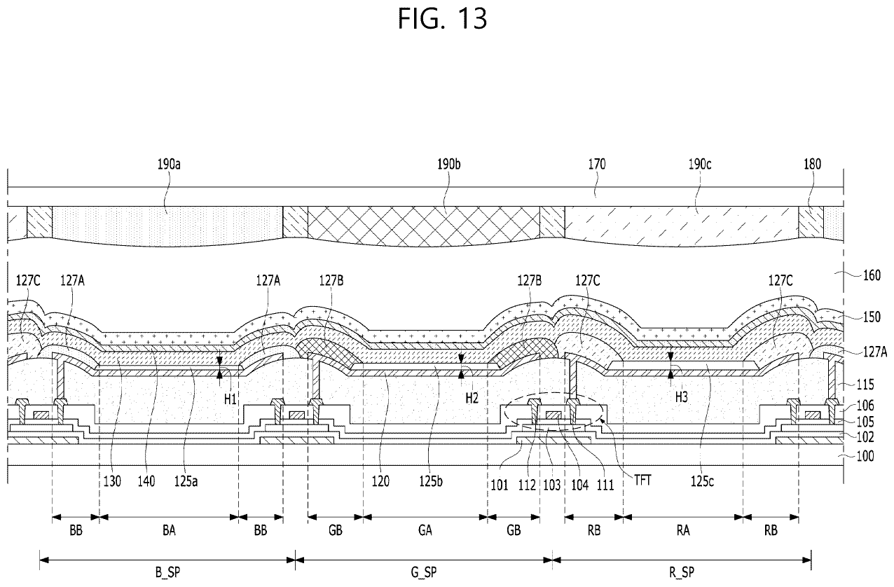

FIG. 12 is a plan view illustrating a light emitting display device according to an embodiment of the present disclosure and FIG. 13 is a cross-sectional view taken along line I-I′ of FIG. 12.

As shown in FIGS. 12 and 13, the light emitting display device according to an embodiment of the present disclosure includes a first light emitting element BEM that emits light of a first wavelength in the first subpixel B_SP, a second light emitting element GEM that emits light of a second wavelength that is longer than the first wavelength in the second subpixel G_SP, and a third light emitting element GEM that is provided in the third subpixel R_SP and emits light of a third wavelength that is longer than the second wavelength.

For example, the first wavelength of light may be a blue wavelength. Blue wavelength light emitted from the first light emitting element BEM may have an emission peak at 420 nm to 490 nm.

For example, the second wavelength of light may be a green wavelength. Green wavelength light emitted from the second light emitting element GEM may have an emission peak at 500 nm to 590 nm.

For example, the third wavelength of light may be a red wavelength. Red wavelength light emitted from the third light emitting element REM may have an emission peak at 600 nm to 650 nm.

Each of the first to third light emitting elements BEM, GEM, REM includes first light emitting portions BA, GA, and RA defined by each opening of the first to third patterns 127A, 127B, 127C, and second light emitting portions BB, GB and RB surrounding the light emitting portions BA, GA and RA, and overlapping the first to third patterns 127A, 127B, 127C. The second light emitting portions BB, GB, and RB may be areas that overlap the reflective anode 120.

An intermediate non-light emitting portion (not shown) is provided between the first light emitting portions BA, GA, RA and the second light emitting portions BB, GB, RB. The intermediate non-light emitting portion (not shown) may be an area where the transparent electrode 125 overlap the first to third patterns 127A, 127B, and 127C. The intermediate non-light emitting portion (not shown) is an area in which no light is substantially emitted, or is an area that separates the first light emitting portion BA, GA, or RA from the second light emitting portion BB, GB, or RB, and light of which is weaker than the first light emitting portion (not shown) and/or the second light emitting portion BB, GB or RB.

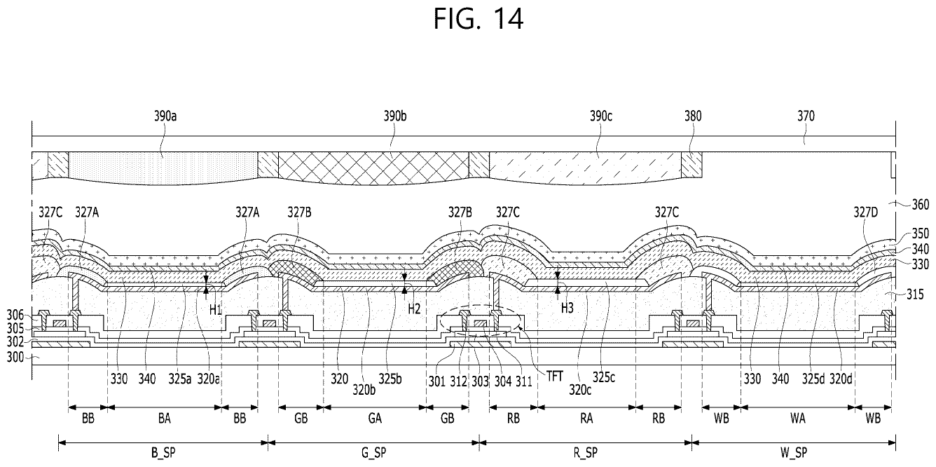

In a plan view, the intermediate non-light emitting portion (not shown) may be formed along the edge shape of the first emitting portion BA, GA, or RA, and may be a closed curve or a discontinuous shape. The intermediate non-light emitting portion (not shown) of each of the first to third light emitting elements BEM, GEM, and REM may have different widths. The width of the intermediate non-light emitting portion (not shown) is determined by the width of the area where the transparent electrode (125a, 125b, 125c in FIG. 13 or 325a, 325b, 325c, 325d in FIG. 14) overlaps the pattern (127A, 127B, 127C in FIG. 13, 327A, 327B, 327C, 327D in FIG. 14). For example, as the thickness of the patterns 127A, 127B, 127C, 327A, 327B, 327C, and 327D decreases, the width of the intermediate non-light emitting portion (not shown) may decrease. The light emitting display device of the present disclosure has second light emitting portions BB, GB, and RB overlapping the first to third patterns 127A, 127B, and 127C, thus advantageously expanding the light emitting area around the first light emitting portions BA, GA, RA, increasing the light emitting area over the entire substrate 100, and providing high resolution.

As shown in FIGS. 12 and 13, the light emitting display device according to an embodiment of the present disclosure includes a substrate 100 including a first subpixel B_SP, a second subpixel G_SP, and a third subpixel R_SP, a planarization film 115 provided on the substrate 100 and including a recess (115H in FIG. 2) having a bottom surface (see 115B in FIG. 2) and an inclined surface (115S in FIG. 2) around the bottom surface (see 115S in FIG. 2) in each of the first to third subpixels B_SP, G_SP, and R_SP, a first reflective anode 120a, a second reflective anode 120b, and a third reflective anode 120c provided in the first to third subpixels B_SP, G_SP, and R_SP along the bottom surface and the side surface, respectively, a first transparent electrode 125a, a second transparent electrode 125b, and a third transparent electrode 125c having different thicknesses TH1, TH2, and TH3 on the first to third reflective anodes 120a, 120b, and 120c disposed on the bottom surface of the recess 125b, a first pattern 127A, a second pattern 127B, and a third pattern 127C, respectively, overlapping the first to third reflective anodes 120a, 120b, and 120c disposed on the side surface of the recess 115H, an intermediate layer 130 disposed on the first to third patterns 127A, 127B, and 127C, and the first to third transparent electrodes 125a, 125b, and 125c, and a cathode 140 disposed on the intermediate layer.

The thicknesses TH1, TH2, and TH3 of the first to third transparent electrodes 125a, 125b, and 125c may be adjusted to correspond to the optical distance (nd) of the m^{th} order required for the corresponding wavelength of the front light emitting portion.

A light emitting display device according to an embodiment of the present disclosure may further include a first color conversion layer 190a, a second color conversion layer 190b, and a third color conversion layer 190c that transmit light with different wavelengths, corresponding to the first to third subpixels (B_SP, G_SP, R_SP), on the cathode 140.

The example illustrated in FIGS. 12 and 13 shows a configuration in which the display device further includes a capping layer 150 and a filler 160 on the cathode 140.

The first to third color conversion layers 190a, 190b, and 190c may be provided on the counter substrate 170 as shown in the drawing. Alternatively, the first to third color conversion layers 190a, 190b, and 190c may be provided on the capping layer 150 without the filler 160, or may be provided on a separate encapsulation layer further provided on the capping layer 150.

The first to third patterns 127A, 127B, and 127C may have different thicknesses depending on different resonance characteristics.

The first to third patterns 127A, 127B, and 127C may contain a material having a refractive index less than the average refractive index of the intermediate layer 130.

The first pattern 127A includes the same material as the first color conversion layer 190a, the second pattern 127B includes the same material as the second color conversion layer 190b, and the third pattern 127C includes the same material as the third color conversion layer 190c. The first to third patterns 127A, 127B, and 127C, and the first to third color conversion layers 190a, 190b, and 190c may be color filters. The first to third patterns 127A, 127B, and 127C may contain a transparent insulating material and may contain a transparent organic insulating material having a refractive index different from that of the planarization film 115. The first to third patterns 127A, 127B, and 127C may be formed of the same transparent organic insulating material and have different thicknesses to provide different resonance effects.

The first pattern 127A is thinner than the first color conversion layer 190a, the second pattern 127B is thinner than the second color conversion layer 190b, and the third pattern 127C is thinner than the third color conversion layer 190c. This aims at increasing the light transmission characteristics of the first to third patterns 127A, 127B, and 127C on the side surface light emitting portion when resonance occurs between the reflective anode 120 and the cathode 140.

The total thickness (D1 in FIG. 3) of the first transparent electrode 125a and the intermediate layer 130 on the bottom surface 115B of the recess of the planarization film 115 in the first subpixel B_SP, and the total thickness (D2 in FIG. 3) of the first pattern 127A and the intermediate layer 130 on the side surface 115S of the recess of the planarization film 115 are independently proportional to the first wavelength transmitted by the first color conversion layer 190a, the total thickness of the second transparent electrode 125b and the intermediate layer 130 on the bottom surface 115B of the recess in the second subpixel G_SP, and the total thickness of the second pattern 127B and the intermediate layer 130 on the side surface 115S of the recess are independently proportional to the second wavelength transmitted by the second color conversion layer 190b, and the total thickness of the third transparent electrode 125c and the intermediate layer 130 on the bottom surface 115B of the recess in the third subpixel R_SP on the side surface 115S of the recess 127B, and the total thickness of the third pattern 127C and the intermediate layer 130 on the side surface 115S of the recess are independently proportional to the third wavelength transmitted by the third color conversion layer 190c.

The counter substrate 370 may include a light blocking layer 380 between the first to third color conversion layers 190a, 190b, and 190c.

The first to third patterns 127A, 127B, and 127C are formed to be thinner than the first to third color conversion layers 190a, 190b and 190c of the counter substrate 170 to maximize or increase side light efficiency from the side surface 115S of the recess 115H.

Descriptions of the same symbols described in FIGS. 2 and 3 are omitted.

Meanwhile, the examples of FIGS. 12 and 13 illustrate a light emitting display device including first to third subpixels that emit different colors.

A light emitting display device including a fourth subpixel with different light emitting characteristics in addition to the first to third subpixels according to another embodiment will be described.

FIG. 14 is a cross-sectional view illustrating a display device according to one embodiment.

As shown in FIG. 14, the light emitting display device according to an embodiment of the present disclosure includes a first light emitting element BEM that emits light of a first wavelength in the first subpixel B_SP, a second light emitting element GEM that emits light of a second wavelength that is longer than the first wavelength in the second subpixel G_SP, and a third light emitting element GEM that is provided in the third subpixel R_SP and emits light of a third wavelength that is longer than the second wavelength, and further includes a fourth light emitting element GEM that emits white light in the fourth subpixel W_SP.

For example, the first wavelength of light may be a blue wavelength. The second wavelength of light may be a green wavelength. The third wavelength of light may be a red wavelength.

As shown in FIG. 14, the light emitting display device according to an embodiment of the present disclosure includes a planarization film 315 including a recess 315H having a bottom surface 315B and an inclined surface 315S around the bottom surface 315B in each of the first to fourth subpixels (B_SP, G_SP, R_SP, W_SP), a first reflective anode 320a, a second reflective anode 320b, a third reflective anode 320c, and a fourth reflective anode 320d provided in the first to fourth subpixels (B_SP, G_SP, R_SP, W_SP) along the bottom surface and the side surface, respectively, a first transparent electrode 325a, a second transparent electrode 325b, a third transparent electrode 325c, and a fourth transparent electrode 325d on the first to fourth reflective anodes 320a, 320b, 320c and 320d disposed on the bottom surface of the recess, a first pattern 327A, a second pattern 327b, a third pattern 327C and a fourth pattern 327d, respectively, overlapping the first to fourth reflective anodes 320a, 320b, 320c and 320d disposed on the side surface of the recess, an intermediate layer 330 disposed on the first to fourth patterns 327A, 327B, 327C, and 327d, and the first to fourth transparent electrodes 325a, 325b, 325c, and 325d, and a cathode 340 disposed on the intermediate layer.

The intermediate layer 330 emits white light and the fourth subpixel W_SP transmits white light through the counter substrate 370 without selective transparency for a specific wavelength because a color conversion layer is not disposed in the fourth subpixel W_SP.

The fourth subpixel W_SP is further included between the third subpixel R_SP and the first subpixel B_SP, and the fourth subpixel W_SP includes a fourth reflective anode 320d provided along the bottom surface 315B and the side surface 315S of the recess, a fourth transparent electrode 325d on the fourth reflective anode 320d, and a fourth pattern 327D located on the side surface 315S of the recess and overlapping the fourth reflective anode 320d exposed from the fourth transparent electrode 325d.

The thickness of the fourth transparent electrode 325d may be different from the thickness of each of the first to third transparent electrodes 325a, 325b, and 325c. In some cases, the fourth transparent electrode 325d may have the same thickness as any one of the first to third transparent electrodes 325a, 325b, and 325c.

Light emitted from the fourth subpixel W_SP may pass through the counter substrate 370 and then may render white.

The counter substrate 370 may include a light blocking layer 380 between the first to third color conversion layers 390a, 390b, and 390c.

The first to fourth patterns 327A, 327B, 327C, and 327D may be thinner than each of the first to third color conversion layers 390a, 390b, and 390c to maximize or increase the side light efficiency from the side surface 315S of the recess 315H.

A buffer layer 302 may be disposed on the substrate 300 to cover the light-shielding layer 301. The buffer layer 302 may be formed on the entire top surface of the substrate 300 to block ions or impurities diffusing from the substrate 300 and to block moisture permeating into the organic light emitting diode (OLED) through the substrate 300.

A thin film transistor TFT and a storage capacitor may be disposed on the buffer layer 302. The thin film transistor TFT may be disposed in each of a plurality of subpixels on the buffer layer 302. For example, the thin film transistor TFT includes an active layer 303, a gate electrode 304 overlapping the active layer 303 with the gate insulating film 305 interposed therebetween, and a source electrode 312 and a drain electrode 311.

The active layer 303 of the thin film transistor TFT may be formed of a silicon or oxide semiconductor material on the buffer layer 302. The active layer 303 may include a channel region overlapping the gate electrode 304 and source/drain regions connected to each of the source electrode 312 and the drain electrode 311.

A gate insulating layer 305 may be formed on the active layer 303. The gate insulating film 305 may be disposed on the channel region of the active layer 303 and may function to insulate the active layer 303 and the gate electrode 305. The gate insulating film 305 may be formed of an inorganic insulating material, for example, a silicon oxide film (SiOx), a silicon nitride film (SiNx), a silicon oxynitride film (SiOxNy), or a multilayer film thereof.

A gate electrode 304 may be formed on the gate insulating film 305. The gate electrode 304 may face the active layer 303 with the gate insulating film 305 interposed therebetween.

An interlayer insulating film 306 covering the gate electrode 304 may be formed on the buffer layer 302. In addition, the interlayer insulating film 306 may function to protect at least one electrode and the active layer 303 of the thin film transistor TFT. The interlayer insulating film 306 may be formed of an inorganic insulating material. For example, the interlayer insulating film 106 may be formed as a silicon oxide film (SiOx), a silicon nitride film (SiNxa), a silicon oxynitride film (SiOxNy), or a multilayer film thereof.

A source electrode 312 and a drain electrode 311 may be formed on the interlayer insulating film 306. To bring the active layer 303 into contact with the source electrode 312 and the drain electrode 311, the corresponding area of the interlayer insulating film 306 may be removed. For example, the source electrode 312 and the drain electrode 311 contact the active layer 303 through a contact hole penetrating the interlayer insulating layer 306 and the gate insulating layer 305 and may be electrically connected to the active layer 303.

The source electrode 312 and the drain electrode 311 may be formed of a single layer or multiple layers. When the source electrode 312 and the drain electrode 311 are a single layer, the single layer is formed of any one selected from the group consisting of the group consisting of molybdenum (Mo), aluminum (Al), chromium (Cr), gold (Au), titanium (Ti), nickel (Ni), neodymium (Nd) and copper (Cu), or an alloy thereof. In addition, when the source electrode 312 and the drain electrode 311 are provided as multiple layers, they may have a double-layer structure of molybdenum/aluminum-neodymium, molybdenum/aluminum, titanium/aluminum, or copper/molytitanium. Alternatively, the source electrode 312 and the drain electrode 311 may have a tri-layer structure of molybdenum/aluminum-neodymium/molybdenum, molybdenum/aluminum/molybdenum, titanium/aluminum/titanium, or molytitanium/copper/molytitanium, but are not limited thereto. The first and second source/drain electrodes SD1 and SD2, and the auxiliary power electrode APE are formed of multiple layers containing any one selected from the group consisting of molybdenum (Mo), aluminum (Al), chromium (Cr), gold (Au), titanium (Ti), nickel (Ni), neodymium (Nd), and copper (Cu), or an alloy thereof.

The light emitting display device of the present disclosure has a recess of the planarization film, and the bottom surface of the recess is used for front light emission and the side surface of the recess is used for side light emission to expand the light emitting portion. In other words, the three-dimensional area of XYZ based on the side surfaces as well as the XY plane are used for light emission to maximize or increase light emission efficiency in the same area.

In addition, the light emitting display device of the present disclosure can improve front luminance depending on the wavelength of each subpixel by further arranging transparent electrodes in the pattern openings and adjusting the thickness of the transparent electrodes for each subpixel.

The light emitting display device of the present disclosure includes the reflective anode below the transparent electrode extending to the area overlapping the pattern, so that light generated from the light emitting element within the opening is incident on the outer side of the opening and is reflected from the reflective electrode within the area overlapping the pattern, thereby increasing the amount of light emitted outside the front as well. Therefore, it is possible to lower the luminance change caused by the viewing angle change, reduce luminance variability depending on the viewing angle, and thereby improve the user's visual perception.

In addition, the light emitting display device of the present disclosure has an effect of reducing the luminance variability depending on the viewing angle by setting the thickness of the pattern to match the cavity characteristics of an order larger than that of the opening in the overlapping area between the pattern and the reflective anode, and inducing reflection suitable for constructive interference at the interface between the surface of the pattern and the intermediate layer to provide the resonance between the reflective anode and the cathode and the resonance between the surface of the pattern, and the interface of the intermediate layer and the cathode.

In addition, the light emitting display device of the present disclosure has the advantage of providing both low-power operation and improved efficiency using the extended light emitting portion by the side mirror. Accordingly, the light emitting display device of the present disclosure has an ESG (environmental/social/governance) effect in terms of eco-friendliness, low power consumption, and process optimization.

A light emitting display device according to one embodiment of the present disclosure may comprise a substrate including a plurality of subpixels, a planarization film provided on the substrate and including a recess having a bottom surface and an inclined side surface around the bottom surface at each subpixel, a reflective anode on the bottom surface and the side surface, a transparent electrode on the reflective anode positioned on the bottom surface of the recess, a pattern overlapping the side surface of the recess with interposing the reflective anode between the pattern and the side surface of the recess, an intermediate layer on the pattern and the transparent electrode and a cathode on the intermediate layer.

A light emitting display device according to one embodiment of the present disclosure may further comprise a color conversion layer on the cathode.

In a light emitting device according to one embodiment of the present disclosure, the planarization film may have a top surface between a plurality of recesses. The pattern may have different thicknesses on the top surface of the planarization film at adjacent subpixels.

In a light emitting device according to one embodiment of the present disclosure, the pattern may comprise a material having a refractive index lower than an average refractive index of the intermediate layer.

In a light emitting device according to one embodiment of the present disclosure, the pattern may comprise the same material as the color conversion layer.

In a light emitting device according to one embodiment of the present disclosure, the pattern may be thinner than the color conversion layer.

A light emitting device according to one embodiment of the present disclosure, may further comprise a light blocking layer on the cathode, the light blocking layer facing an area of the pattern that does not overlap the reflective anode.

In a light emitting device according to one embodiment of the present disclosure, at at least one of the plurality of subpixels, a total thickness of the transparent electrode and the intermediate layer between the reflective anode and the cathode on the bottom surface of the recess is a first thickness. A total thickness of the pattern and the intermediate layer between the reflective anode and the cathode on the side surface of the recess is a second thickness. Each of the first thickness and the second thickness may be independently proportional to a wavelength transmitted by the color conversion layer.

In a light emitting device according to one embodiment of the present disclosure, 9 a first resonance between the reflective anode and the cathode on the bottom surface of the recess and a second resonance between the reflective anode and the cathode on the side surface of the recess of the planarization film may be determined by different orders.

In a light emitting device according to one embodiment of the present disclosure, the color conversion layer may be provided on a counter substrate. The light emitting display device may further comprise at least one of a capping layer, a protective film, and a filler between the color conversion layer and the cathode.

In a light emitting display device device according to one embodiment of the present disclosure, an inner angle between the side surface of the recess and the bottom surface of the recess may be an obtuse angle. The reflective anode exposed from the transparent electrode may be disposed on the side surface of the recess. The pattern may overlap an edge of the transparent electrode provided on the bottom surface of the recess and contacts the top surface of the reflective anode.

In a light emitting device according to one embodiment of the present disclosure, the plurality of subpixels comprise a first subpixel, a second subpixel, and a third subpixel. The light emitting display device further comprises a first color conversion layer, a second color conversion layer, and a third color conversion layer on the cathode, at the first subpixel, the second subpixel, and the third subpixel, respectively. A wavelength of transmitted light may increase in the order of the first color conversion layer, the second color conversion layer, and the third color conversion layer. The transparent electrode may have different thicknesses at the first to third subpixels.

In a light emitting device according to one embodiment of the present disclosure, the pattern comprises a first pattern, a second pattern, and a third pattern having different thicknesses at the first subpixel, the second subpixel, and the third subpixel, respectively. The first pattern and the second pattern may overlap between the first subpixel and the second subpixel. The second pattern and the third pattern may overlap between the second subpixel and the third subpixel. Also the third pattern and the first pattern may overlap between the third subpixel and the first subpixel.

In a light emitting device according to one embodiment of the present disclosure, the intermediate layer may comprise an organic layer that emits a white light.

In a light emitting device according to one embodiment of the present disclosure, the intermediate layer may comprise two or more light emitting layers emitting light of different colors, and a charge generation layer between the two or more light emitting layers.

In a light emitting device according to one embodiment of the present disclosure, the intermediate layer may comprise light emitting layers emitting different colors at adjacent subpixels.

In a light emitting device according to one embodiment of the present disclosure, the intermediate layer may comprise three or more light emitting layers, and at least two of the three or more light emitting layers comprise light emitting layers emitting light with the same color.

In a light emitting device according to one embodiment of the present disclosure, the intermediate layer may comprise three or more light emitting layers emitting light with different colors. Among the three or more light emitting layers, a first light emitting layer emitting light of a first color is spaced apart from other light emitting layers emitting light of different color from the first color with a charge generation layer and a common layer interposed therebetween. At least two of the light emitting layers emitting light of different color from the first light emitting layer may be in contact with each other.

A light emitting display device according to one embodiment of the present disclosure may comprise a substrate including a first subpixel, a second subpixel and a third subpixel, a planarization film provided on the substrate and including a recess having a bottom surface and an inclined side surface around the bottom surface at each of the first to third subpixels, a first reflective anode, a second reflective anode, and a third reflective anode provided at the first to third subpixels, respectively, on the bottom surface and the side surface of each recess, a first transparent electrode, a second transparent electrode, and a third transparent electrode having different thicknesses, respectively, on the first to third reflective anodes positioned at the bottom surface of the recess, a first pattern, a second pattern, and a third pattern, respectively, overlapping the first to third reflective anodes disposed on the side surface of the recess, an intermediate layer on the first to third patterns and the first to third transparent electrodes; and a cathode on the intermediate layer.

A light emitting device according to one embodiment of the present disclosure, may further comprise a first color conversion layer, a second color conversion layer, and a third color conversion layer on the cathode corresponding to the first to third subpixels, respectively. The first color conversion layer, the second color conversion layer, and the third color conversion layer may transmit different wavelengths.

A light emitting display device according to one embodiment of the present disclosure may further comprise a fourth subpixel between the third subpixel and the first subpixel. The fourth subpixel may comprise a fourth reflective anode on the bottom surface and the side surface of the recess corresponding to the fourth subpixel, a fourth transparent electrode on the fourth reflective anode and a fourth pattern on the side surface of the recess and overlapping the fourth reflective anode exposed from the fourth transparent electrode. The fourth transparent electrode may have a thickness different from that of each of the first to third transparent electrodes.

A light emitting display device according to one embodiment of the present disclosure may further comprising a fourth subpixel between the third subpixel and the first subpixel. And the fourth subpixel may comprise a fourth reflective anode provided on the bottom surface and the side surface of the recess corresponding to the fourth subpixel, a fourth transparent electrode on the fourth reflective anode and a fourth pattern disposed on the side surface of the recess and overlapping the fourth reflective anode exposed from the fourth transparent electrode. The fourth transparent electrode may have the same thickness as any one of the first to third transparent electrodes.

In a light emitting display device according to one embodiment of the present disclosure, a light emitted from the fourth subpixel may passes through a counter substrate and may be then emitted as white light.

In a light emitting display device according to one embodiment of the present disclosure, the first to third patterns may have different thicknesses.

In a light emitting display device according to one embodiment of the present disclosure, the first to third patterns may comprise a material having a refractive index lower than an average refractive index of the intermediate layer.

In a light emitting display device according to one embodiment of the present disclosure, the first pattern may comprise the same material as the first color conversion layer. The second pattern may comprise the same material as the second color conversion layer, and the third pattern may comprise the same material as the third color conversion layer.

In a light emitting display device according to one embodiment of the present disclosure, the first pattern may be thinner than the first color conversion layer, the second pattern may be thinner than the second color conversion layer, and the third pattern may be thinner than the third color conversion layer.

In a light emitting display device according to one embodiment of the present disclosure, a total thickness of the first transparent electrode and the intermediate layer on the bottom surface of the recess at the first subpixel and a total thickness of the first pattern and the intermediate layer on the side surface of the recess may be independently proportional to a first wavelength transmitted by the first color conversion layer. Also, a total thickness of the second transparent electrode and the intermediate layer on the bottom surface of the recess at the second subpixel and a total thickness of the second pattern and the intermediate layer on the side surface of the recess may be independently proportional to a second wavelength transmitted by the second color conversion layer. A total thickness of the third transparent electrode and the intermediate layer on the bottom surface of the recess at the third subpixel, and a total thickness of the third pattern and the intermediate layer on the side surface of the recess may be independently proportional to a third wavelength transmitted by the third color conversion layer.

As apparent from the foregoing, the light emitting display device of the present disclosure has the following effects.

The light emitting display device of the present disclosure has a recess of the planarization film and is capable of expanding the light emitting portion using the bottom surface of the recess for front light emission and using the side surface of the recess for side light emission. In other words, light emission efficiency can be maximized or increased in the same area using the three-dimensional area of XYZ based on the side surfaces as well as the XY plane for light emission.

In addition, the light emitting display device of the present disclosure can improve front luminance depending on the wavelength of each subpixel by further arranging transparent electrodes in the pattern openings and adjusting the thickness of the transparent electrodes for each subpixel.

The light emitting display device of the present disclosure includes the reflective anode below the transparent electrode extending to the area overlapping the pattern, so that light generated from the light emitting element within the opening is incident on the outer side of the opening and is reflected from the reflective electrode within the area overlapping the pattern, thereby increasing the amount of light emitted outside the front as well. Therefore, it is possible to lower the luminance change caused by the viewing angle change, reduce luminance variability depending on the viewing angle, and thereby improve the user's visual perception.

In addition, the light emitting display device of the present disclosure has an effect of reducing the luminance variability depending on the viewing angle by setting the thickness of the pattern to match the cavity characteristics of an order larger than that of the opening in the overlapping area between the pattern and the reflective anode, and inducing reflection suitable for constructive interference at the interface between the surface of the pattern and the intermediate layer to provide the resonance between the reflective anode and the cathode and the resonance between the surface of the pattern, and the interface of the intermediate layer and the cathode.

In addition, the light emitting display device of the present disclosure has the advantage of providing both low-power operation and improved efficiency using the extended light emitting portion by the side mirror. Accordingly, the light emitting display device of the present disclosure has an ESG (environmental/social/governance) effect in terms of eco-friendliness, low power consumption, and process optimization.

It will be apparent to those skilled in the art that various modifications and variations can be made in the disclosure without departing from the spirit or scope of the disclosure. Thus, it is intended that the disclosure cover such modifications and variations thereof, provided they fall within the scope of the appended claims and their equivalents.

What is claimed is:

1. A light emitting display device, comprising:
a substrate including a plurality of subpixels;
a planarization film on the substrate and including a recess having a bottom surface and an inclined side surface around the bottom surface at each subpixel;
a reflective anode on the bottom surface and the side surface of the recess;
a transparent electrode on the reflective anode positioned on the bottom surface of the recess;
a pattern overlapping the side surface of the recess with interposing the reflective anode between the pattern and the side surface of the recess;
an intermediate layer on the pattern and the transparent electrode; and
a cathode on the intermediate layer.

2. The light emitting display device according to claim 1, further comprising a color conversion layer on the cathode.

3. The light emitting display device according to claim 1, wherein:
the planarization film has a top surface between a plurality of recesses; and
the pattern has different thicknesses on the top surface of the planarization film at adjacent subpixels.

4. The light emitting display device according to claim 1, wherein the pattern comprises a material having a refractive index lower than an average refractive index of the intermediate layer.

5. The light emitting display device according to claim 2, wherein the pattern comprises the same material as the color conversion layer.

6. The light emitting display device according to claim 2, wherein the pattern is thinner than the color conversion layer.

7. The light emitting display device according to claim 1, further comprising a light blocking layer on the cathode, the light blocking layer facing an area of the pattern that does not overlap the reflective anode.

8. The light emitting display device according to claim 2, wherein, at at least one of the plurality of subpixels:
a total thickness of the transparent electrode and the intermediate layer between the reflective anode and the cathode on the bottom surface of the recess is a first thickness;
a total thickness of the pattern and the intermediate layer between the reflective anode and the cathode on the side surface of the recess is a second thickness; and
each of the first thickness and the second thickness is independently proportional to a wavelength transmitted by the color conversion layer.

9. The light emitting display device according to claim 1, wherein a first resonance between the reflective anode and the cathode on the bottom surface of the recess and a second resonance between the reflective anode and the cathode on the side surface of the recess of the planarization film are determined by different orders.

10. The light emitting display device according to claim 2, wherein:
the color conversion layer is provided on a counter substrate; and
the light emitting display device further comprises at least one of a capping layer, a protective film, and a filler between the color conversion layer and the cathode.

11. The light emitting display device according to claim 1, wherein:
an inner angle between the side surface of the recess and the bottom surface of the recess is an obtuse angle, and the reflective anode exposed from the transparent electrode is disposed on the side surface of the recess; and
the pattern overlaps an edge of the transparent electrode provided on the bottom surface of the recess and contacts the top surface of the reflective anode.

12. The light emitting display device according to claim 1, wherein:
the plurality of subpixels comprise a first subpixel, a second subpixel, and a third subpixel;
the light emitting display device further comprises a first color conversion layer, a second color conversion layer, and a third color conversion layer on the cathode, at the first subpixel, the second subpixel, and the third subpixel, respectively, and a wavelength of transmitted light increases in the order of the first color conversion layer, the second color conversion layer, and the third color conversion layer; and
the transparent electrode has different thicknesses at the first to third subpixels.

13. The light emitting display device according to claim 12, wherein:
the pattern comprises a first pattern, a second pattern, and a third pattern having different thicknesses at the first subpixel, the second subpixel, and the third subpixel, respectively; and
the first pattern and the second pattern overlap between the first subpixel and the second subpixel, the second pattern and the third pattern overlap between the second subpixel and the third subpixel, and the third pattern and the first pattern overlap between the third subpixel and the first subpixel.

14. The light emitting display device according to claim 1, wherein the intermediate layer comprises an organic layer that emits a white light.

15. The light emitting display device according to claim 1, wherein the intermediate layer comprises two or more light emitting layers emitting light of different colors, and a charge generation layer between the two or more light emitting layers.

16. The light emitting display device according to claim 1, wherein the intermediate layer comprises light emitting layers emitting different colors at adjacent subpixels.

17. The light emitting display device according to claim 1, wherein the intermediate layer comprises three or more light emitting layers, and at least two of the three or more light emitting layers comprise light emitting layers emitting light with the same color.

18. The light emitting display device according to claim 1, wherein:
the intermediate layer comprises three or more light emitting layers emitting light with different colors;
among the three or more light emitting layers, a first light emitting layer emitting light of a first color is spaced apart from other light emitting layers emitting light of different color from the first color with a charge generation layer and a common layer interposed therebetween; and
at least two of the light emitting layers emitting light of different color from the first light emitting layer are in contact with each other.

19. A light emitting display device, comprising:
a substrate including a first subpixel, a second subpixel, and a third subpixel;
a planarization film on the substrate and including a recess having a bottom surface and an inclined side surface around the bottom surface at each of the first to third subpixels;
a first reflective anode, a second reflective anode, and a third reflective anode provided at the first to third subpixels, respectively, on the bottom surface and the side surface of each recess;
a first transparent electrode, a second transparent electrode, and a third transparent electrode having different thicknesses, respectively, on the first to third reflective anodes positioned at the bottom surface of the recess;
a first pattern, a second pattern, and a third pattern, respectively, overlapping the first to third reflective anodes disposed on the side surface of the recess;
an intermediate layer on the first to third patterns and the first to third transparent electrodes; and
a cathode on the intermediate layer.

20. The light emitting display device according to claim 19, further comprising:
a first color conversion layer, a second color conversion layer, and a third color conversion layer on the cathode corresponding to the first to third subpixels, respectively,
wherein the first color conversion layer, the second color conversion layer, and the third color conversion layer transmit different wavelengths.

21. The light emitting display device according to claim 19, further comprising:
a fourth subpixel between the third subpixel and the first subpixel,
wherein the fourth subpixel comprises:
a fourth reflective anode on the bottom surface and the side surface of the recess corresponding to the fourth subpixel;
a fourth transparent electrode on the fourth reflective anode; and
a fourth pattern on the side surface of the recess and overlapping the fourth reflective anode exposed from the fourth transparent electrode, and
wherein the fourth transparent electrode has a thickness different from that of each of the first to third transparent electrodes.

22. The light emitting display device according to claim 19, further comprising a fourth subpixel between the third subpixel and the first subpixel,
wherein the fourth subpixel comprises:
a fourth reflective anode provided on the bottom surface and the side surface of the recess corresponding to the fourth subpixel;
a fourth transparent electrode on the fourth reflective anode; and
a fourth pattern disposed on the side surface of the recess and overlapping the fourth reflective anode exposed from the fourth transparent electrode, and
wherein the fourth transparent electrode has the same thickness as any one of the first to third transparent electrodes.

23. The light emitting display device according to claim 21, wherein light emitted from the fourth subpixel passes through a counter substrate and is then emitted as white light.

24. The light emitting display device according to claim 19, wherein the first to third patterns have different thicknesses.

25. The light emitting display device according to claim 19, wherein the first to third patterns comprise a material having a refractive index lower than an average refractive index of the intermediate layer.

26. The light emitting display device according to claim 20, wherein:
the first pattern comprises the same material as the first color conversion layer;
the second pattern comprises the same material as the second color conversion layer; and
the third pattern comprises the same material as the third color conversion layer.

27. The light emitting display device according to claim 26, wherein:
the first pattern is thinner than the first color conversion layer;
the second pattern is thinner than the second color conversion layer; and
the third pattern is thinner than the third color conversion layer.

28. The light emitting display device according to claim 26, wherein:
a total thickness of the first transparent electrode and the intermediate layer on the bottom surface of the recess at the first subpixel and a total thickness of the first pattern and the intermediate layer on the side surface of the recess are independently proportional to a first wavelength transmitted by the first color conversion layer; and
a total thickness of the second transparent electrode and the intermediate layer on the bottom surface of the recess at the second subpixel and a total thickness of the second pattern and the intermediate layer on the side surface of the recess are independently proportional to a second wavelength transmitted by the second color conversion layer; and
a total thickness of the third transparent electrode and the intermediate layer on the bottom surface of the recess at the third subpixel, and a total thickness of the third pattern and the intermediate layer on the side surface of the recess are independently proportional to a third wavelength transmitted by the third color conversion layer.
